(19) United States
(12) Patent Application Publication
(10) Pub. No.: US 2025/0311098 A1
(43) Pub. Date: Oct. 2, 2025

(54) PRINTED CIRCUIT BOARD

(71) Applicant: SAMSUNG ELECTRO-MECHANICS CO., LTD., Suwon-si (KR)

(72) Inventors: Kwang Hee KWON, Suwon-si (KR); Gun Hwi HYUNG, Suwon-si (KR); Young Hoon KIM, Suwon-si (KR); Jin Gyu OCK, Suwon-si (KR)

(73) Assignee: SAMSUNG ELECTRO-MECHANICS CO., LTD., Suwon-si (KR)

(21) Appl. No.: 19/056,113

(22) Filed: Feb. 18, 2025

(30) Foreign Application Priority Data
Mar. 28, 2024 (KR) 10-2024-0042649

(51) Int. Cl. H05K 1/03; H05K 1/11; H05K 1/18

(52) U.S. Cl. CPC H05K 1/0306; H05K 1/115; H05K 1/181; H05K 2201/09018; H05K 2201/096; H05K 2201/09827

(57) ABSTRACT

A printed circuit board is provided, the printed circuit board including: a glass substrate having an upper surface and a lower surface opposing each other in a first direction, a first side surface and a second side surface opposing each other in a second direction, perpendicular to the first direction, and a third side surface and a fourth side surface opposing each other in a third direction perpendicular to the first and second directions, respectively; and one or more first insulating layers disposed on the upper or lower surface of the glass substrate, wherein each of the first to fourth side surfaces of the glass substrate protrudes from at least a portion of the side surfaces of the one or more first insulating layers in the second or third direction.

### CROSS-REFERENCE TO RELATED APPLICATIONS

This application claims benefit of priority to Korean Patent Application No. 10-2024-0042649 filed on Mar. 28, 2024 in the Korean Intellectual Property Office, the disclosure of which is incorporated herein by reference in its entirety.

### BACKGROUND

### 1. Field

The present disclosure relates to a printed circuit board.

### 2. Description of Related Art

Recently, as the market has changed to focus on large-capacity servers, an amount of data has increased rapidly, and networks, storage, or the like is growing more rapidly and accordingly, new multilayer substrates are being developed. For example, in order to correspond to thin redistribution layers and large-area packages, a technology using a silicon interpose is being developed at a package level, and Fan-out multi-chip module (FOMCM), Fan-out Embedded Bridge (FOEB), Embedded multi-die interconnect bridge (EMIB), and the like are being developed at a substrate level.

Meanwhile, in the case of a silicon interposer and an EMIB connecting different types of chips, to each other, flatness and warpage control are important during package assembly. In particular, in the silicon interposer, flatness and warpage control are superior when assembling large-area packages, but access may be limited due to supply constraints and high costs. On the other hand, the EMIB, or the like, is less expensive than the silicon interposer, but since the EMIB is based on an organic material, a change in an absorption rate and expansion rate depending on a change in temperature and humidity is significant, so that it may be difficult to control warpage during assembly and mounting.

Accordingly, the development of a substrate using a glass substrate as a core layer is required. However, in the case of a glass substrate, cracks can easily occur during a singulation process, and also, the strength of an edge may decrease after singulation, requiring post-processing.

### SUMMARY

An aspect of the present disclosure is to provide a printed circuit board including a glass substrate, which can reduce cracks occurring in the glass substrate due to singulation, and can also improve the strength of an edge of the glass substrate even after singulation.

An aspect of the present disclosure is to reinforce mechanical rigidity and reduce concerns about cracks by controlling a shape of a glass substrate in a structure of a multilayer printed circuit board in which an insulating layer is stacked on the glass substrate.

For example, according to an aspect of the present disclosure, a printed circuit board includes a glass substrate having upper and lower surfaces opposing each other in a first direction, first and second side surfaces opposing each other in a second direction perpendicular to the first direction, and third and fourth side surfaces opposing each other in a third direction perpendicular to the first and second directions, respectively; and one or more first insulating layers disposed on the upper or lower surface of the glass substrate. Each of the first to fourth side surfaces of the glass substrate may protrude from at least a portion of the side surfaces of the one or more first insulating layers in the second or third direction.

For example, according to an aspect of the present disclosure, a printed circuit board includes: a glass substrate; and an insulating layer disposed on the glass substrate. A side surface of the glass substrate may protrude outwardly from a side surface of the insulating layer, and on a cross-section, the protruding side surface of the glass substrate may have a substantially convex curved shape in a central portion.

For example, according to an aspect of the present disclosure, a printed circuit board includes a glass substrate; one or more first insulating layers disposed on an upper surface of the glass substrate; one or more first wiring layers respectively disposed on or within the one or more first insulating layers; and one or more first via layers respectively penetrating at least a portion of at least one of the one or more first insulating layers. The glass substrate includes a portion protruding outwardly from a flat side surface of the one or more first insulating layers.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example embodiment of an electronic device system;

FIG. 2 is a perspective view schematically illustrating an example embodiment of an electronic device;

FIG. 3 is a perspective view schematically illustrating a printed circuit board according to an example embodiment;

FIG. 4 is a schematic cross-sectional view taken along line I-I′ of the printed circuit board of FIG. 3;

FIG. 5 is a plan view schematically illustrating, for example, a top view, of the printed circuit board of FIG. 3 when viewed in a first direction;

FIG. 6 is a cross-sectional view schematically illustrating a modified example of region A of FIG. 4;

FIG. 7 is a cross-sectional view schematically illustrating another modified example of region A of FIG. 4;

FIG. 8 is a cross-sectional view schematically illustrating another modified example of region A of FIG. 4;

FIGS. 9A and 9B are schematic drawings illustrating cutting of a printed circuit board at a panel level using a singulation process using a blade;

FIGS. 10A and 10B are schematic drawings illustrating a grinding process of each printed circuit board cut by a singulation process;

FIGS. 11A and 11B are schematic drawings illustrating cutting of a printed circuit board at a panel level using a singulation process using a blade;

FIG. 12 is a cross-sectional view schematically illustrating a printed circuit board according to another example embodiment;

FIG. 13 is a cross-sectional view schematically illustrating a printed circuit board according to another example embodiment;

FIG. 14 is a cross-sectional view schematically illustrating a printed circuit board according to another example embodiment; and

FIG. 15 is a cross-sectional view schematically illustrating a printed circuit board according to another example embodiment.

### DETAILED DESCRIPTION

Hereinafter, embodiments of the present disclosure will be described as follows with reference to the attached drawings.

### Electronic Device

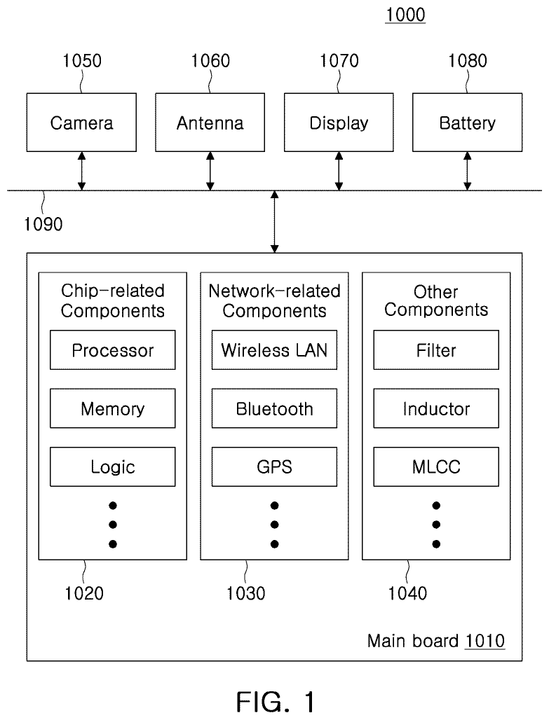

FIG. 1 is a block diagram illustrating an example embodiment of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+(HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

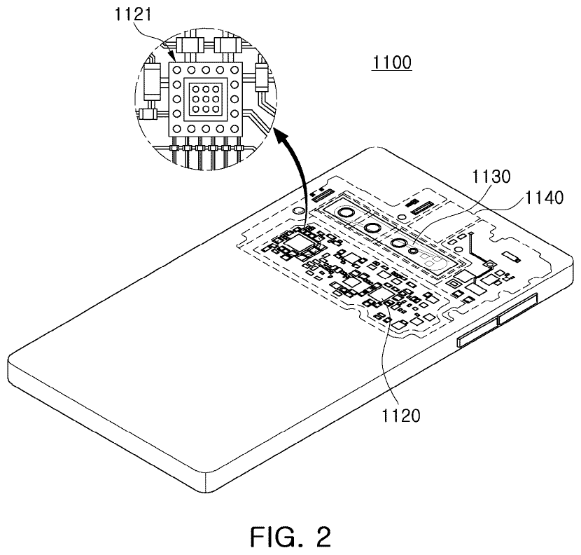

FIG. 2 is a perspective diagram illustrating an example embodiment of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

### Printed Circuit Board

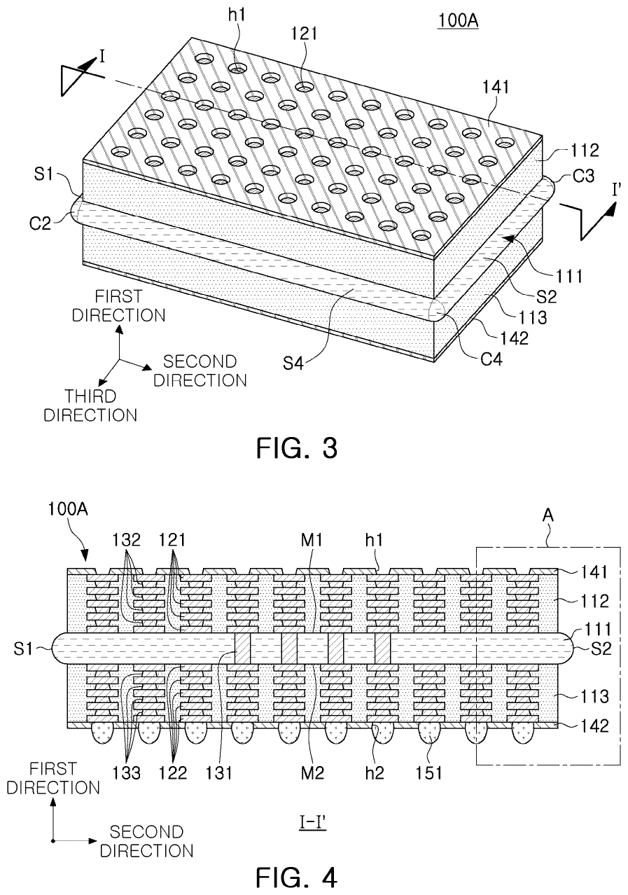

FIG. 3 is a perspective view schematically illustrating a printed circuit board according to an example.

FIG. 4 is a schematic cross-sectional view taken along line I-I′ of the printed circuit board of FIG. 3.

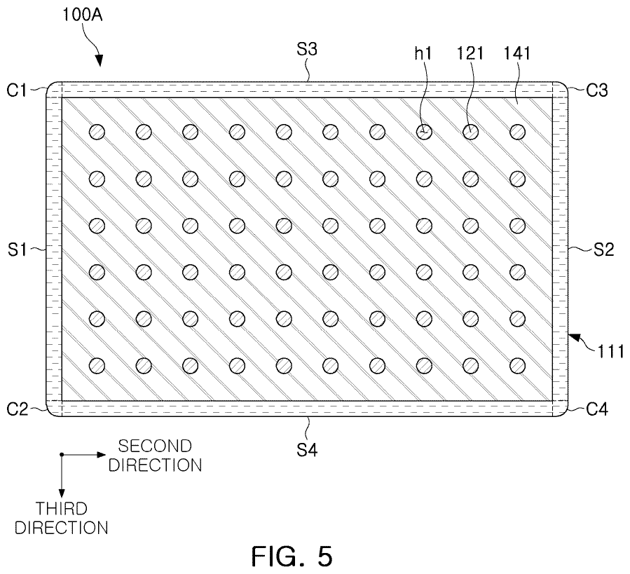

FIG. 5 is a plan view schematically illustrating, for example, a top view, of the printed circuit board of FIG. 3 when viewed in a first direction.

Referring to the drawings, a printed circuit board 100A according to an example may include a glass substrate 111 having an upper surface M1 and a lower surface M2, opposing each other in a first direction, a first side surface S1 and a second side surface S2 opposing each other in a second direction, perpendicular to the first direction, and a third side surface S3 and a fourth side surface S4 opposing each other in a third direction, perpendicular to the first direction and the second direction, respectively, one or more first insulating layers 112 disposed on the upper surface M1 of the glass substrate 111, and one or more second insulating layers 113 disposed on the lower surface M2 of the glass substate 111. Each of the first to fourth side surfaces S1, S2, S3, and S4 of the glass substrate 111 may protrude from at least a portion of the side surfaces of the one or more first insulating layers 112 and/or at least a portion of the side surfaces of the one or more second insulating layers 113 in the second direction or the third direction.

Meanwhile, when singulating a printed circuit board at a panel level into units, securing the quality for the cut surface may be required. There are methods for singulating such as a blade method and a laser method, and the blade method may generally be preferably performed. The blade method may be a grinding method of cutting and grinding a product through diamond grit attached to a blade wheel. Since glass is a brittle material, there may be a risk of cracks and chipping after cutting with such blades, and surface roughness may be formed by diamond particles of the wheel.

In addition, to alleviate this, a grinding process may be performed as a post-processing process after the singulation process, but in the case of a glass substrate, when the side surface of the glass substrate is ground to be flat, an edge of the glass substrate may have an angular shape, so there may be a risk of cracks and reduced strength. To solve this problem, implementing an edge surface of the glass substrate as a curved surface may be considered, but in this case, the edge shape of a top surface of a product may be formed to be curved due to polishing of an insulating layer and a solder resist layer stacked on the glass substrate. Therefore, it may be difficult to observe an exact size of the product because the exact edge surface cannot be detected during the inspection process. In addition, in order to provide sufficient curves to the edge surface of the glass substrate, sacrificing the insulating layer may be inevitable.

On the other hand, in the printed circuit board 100A according to an example, each of the first to fourth side surfaces S1, S2, S3 and S4 of the glass substrate 111 may protrude from at least a portion of the side surfaces of one or more first insulating layers 112 and/or at least a portion of the side surfaces of one or more second insulating layers 113 in the second direction or the third direction. When having such a structure, the mechanical rigidity of the glass substrate 111 may be reinforced and concerns about cracks may be reduced. For example, cracks, chipping, and the like may occur from the cut surface of the glass substrate 111, and therefore, when the first to fourth side surfaces S1, S2, S3, and S4 have a protruding structure, the above-described problems that may occur after the singulation process may be solved. For example, as a pullback length, which is a length from an outermost side of each of the first to fourth side surfaces S1, S2, S3, and S4 of the glass substrate 111 to an inner side thereof covered with one or more first insulating layers 112 and/or one or more second insulating layers 113, in the second direction or the third direction, increases, residual stress may decrease, and thus a stress intensity factor value may decrease. For example, when the pullback length is approximately 500 μm, the stress intensity factor value can be reduced to approximately 1/10 or less. The pullback length is not particularly limited, but can be approximately 500 μm or less.

Meanwhile, the glass substrate 111 may further have a first corner portion C1 connecting the first and third side surfaces S1 and S3, a second corner portion C2 connecting the first and fourth side surfaces S1 and S4, a third corner portion C3 connecting the second and third side surfaces S2 and S3, and a fourth corner portion C4 connecting the second and fourth side surfaces S2 and S4. In this case, when viewed in the first direction, for example, on a plane according to a top view or a bottom view, each of the first to fourth corner portions C1, C2, C3, and C4 may have a substantially curved shape. In addition, when viewed from the second direction or third direction, for example, in a cross-section in the first-second direction or a cross-section in the first-third direction, each of the first to fourth side surfaces S1, S2, S3, and S4 may have a substantially convex curved shape in the central portion. As described above, when the first to fourth corner portions C1, C2, C3, and C4 of the glass substrate 111 have substantially curved shapes, and when each of the first to fourth side surfaces S1, S2, S3, and S4 has a substantially convex curved shape in the central portion, cracks, or the like, in the glass substrate 111 due to singulation may be reduced more effectively, and the strength of the edge of the glass substrate 111 may be improved more effectively even after singulation.

Referring to the drawings, the printed circuit board 100A according to an example may further include: a through-via layer 131 penetrating at least a portion of the glass substrate 111, one or more first wiring layers 121 respectively disposed on or within one or more first insulating layers 112, one or more first via layers 132 respectively penetrating at least a portion of at least one of the one or more first insulating layers 112, one or more second wiring layers 122 respectively disposed on or within one or more second insulating layers 113, and one or more second via layers respectively penetrating at least a portion of at least one of the one or more second insulating layers 113. For example, the printed circuit board 100A may be a multilayer printed circuit board and may be used as a package substrate, or the like.

Referring to the drawings, the printed circuit board 100A according to an example may further include: a first passivation layer 141 disposed on a first insulating layer 112 disposed on an uppermost side among one or more first insulating layers 112 and having one or more first openings h1 respectively exposing at least a portion of a first wiring layer 121 disposed on an uppermost side among one or more first wiring layers 121, a second passivation layer 142 disposed on a second insulating layer 113 disposed on a lowermost side among one or more second insulating layers 113 and having one or more second openings h2 respectively exposing at least a portion of a second wiring layer 122 disposed on a lowermost side among one or more second wiring layers 122, and one or more electrical connection metals 151 respectively disposed on the one or more second openings h2 and respectively connected to at least a portion of the exposed second wiring layer 122 disposed on the lowermost side among the one or more second wiring layers 122. For example, the printed circuit board 100A may have a Ball Grid Array (BGA) structure and may be used as a package substrate, or the like.

Hereinafter, components of a printed circuit board 100A according to an example will be described in more detail with reference to the drawings.

The glass substrate 111 may include glass, an amorphous solid. The glass may include, for example, pure silicon dioxide (about 100% SiO₂), soda-lime glass, borosilicate glass, alumino-silicate glass, or the like. However, the present disclosure is not limited thereto, and alternative glass materials, such as fluorine glass, phosphate glass, chalcogen glass, or the like, may also be used as a material thereof. In addition, other additives may be further included to form glass having specific physical properties. These additives may include calcium carbonate (e.g., lime) and sodium carbonate (e.g., soda), as well as magnesium, calcium, manganese, aluminum, lead, boron, iron, chromium, potassium, sulfur and antimony, and carbonates and/or oxides of these and other elements. The glass substrate 111 may be distinguished from an organic insulating material including glass fibers (glass cloth, and/or glass fabric), such as copper clad laminate (CCL), and prepreg (PPG), and for example, may include plate glass.

Each of the first and second insulating layers 111 and 112 may include an organic insulating material. The organic insulating material may include a thermosetting resin such as epoxy resin, a thermoplastic resin such as polyimide, or a material including inorganic filler, organic filler, and/or glass fiber along with the resin. For example, the organic insulating material may be Prepreg (PPG), Ajinomoto Build-up Film (ABF), Photo Imageable Dielectric (PID), and the like, but an embodiment thereof is not limited thereto. Each of the first and second insulating layers 112 and 113 may be a plurality of layers. The first and second insulating layers 112 and 113 may be disposed with the glass substate 111 interposed therebetween in the first direction. The first and second insulating layers 112 and 113 may have substantially symmetrical structures with respect to each other. For example, the materials and number of layers thereof may be substantially the same.

Each of the first and second wiring layers 121 and 122 may include a metal material. The metal material may include copper (Cu), aluminum (Al), silver (Ag), tin (Sn), gold (Au), nickel (Ni), lead (Pb), titanium (Ti), and/or alloys thereof. Preferably, the metal material may include copper (Cu), but an embodiment thereof is not limited thereto. Each of the first and second wiring layers 121 and 122 may perform various functions depending on a design thereof. For example, each of the first and second wiring layers 121 and 122 may include a signal pattern, a power pattern, and a ground pattern. Each of the patterns may have various forms such as a line, a plain, and a pad. Each of the first and second wiring layers 121 and 122 may include a seed layer and a plating layer. The seed layer may be formed by electroless plating (or chemical copper), and may be formed by a sputtering process, if necessary, or both thereof may be used. Each of the first and second wiring layers 121 and 122 may be a plurality of layers corresponding to the first and second insulating layers 112 and 113 when the first and second insulating layers 112 and 113 are a plurality of layers. Each of the first and second wiring layers 121 and 122 may be independently protruded on or embedded in the first and second insulating layers 112 and 113.

The through-via layer 131 may include a metal material. The metal material may include copper (Cu), aluminum (Al), silver (Ag), tin (Sn), gold (Au), nickel (Ni), lead (Pb), titanium (Ti), and/or alloys thereof, and preferably, the metal material may include copper (Cu), but an embodiment thereof is not limited thereto. The through-via layer 131 may include a plurality of through-vias penetrating between the upper and lower surfaces of the glass substrate 111, thereby providing an electrical connection path in the first direction within the glass substrate 111. Each of the plurality of through-vias may perform various functions depending on a design of the corresponding layer. For example, the plurality of through-vias may include a ground via, a power via, and a signal via. The through-via layer 131 may a seed layer and a plating layer. The seed layer may be formed by electroless plating (or chemical copper), and may also be formed by a sputtering process if necessary. Alternatively, both a sputtering layer and an electroless plating layer may be included. The plating layer may be formed by electrolytic plating (or electroplating).

Each of the first and second via layers 131 and 132 may include a metal material. The metal material may include copper (Cu), aluminum (Al), silver (Ag), tin (Sn), gold (Au), nickel (Ni), lead (Pb), titanium (Ti), and/or alloys thereof, and preferably, the metal material may include copper (Cu), but an embodiment thereof is not limited thereto. Each of the first and second via layers 131 and 132 may include a plurality of connection vias penetrating at least a portion of each of the first and second insulating layers 112 and 113, thereby providing an electrical connection path in the first direction within the first and second insulating layers 112 and 113, respectively. Each of the connection vias may perform various functions depending on a design of the corresponding layer. For example, the connection vias may include a signal via, a power via, a ground via, and the like. Each of the connection vias may include a filled via in which a via hole is filled with a metal material, but may also include a conformal via in which the metal material is disposed along a wall surface of the via hole. Each of the plurality of connection vias may have a tapered shape on a cross-section. For example, the plurality of connection vias of the first via layer 132 may have a tapered shape of which a width of the upper surface is wider than a width of the lower surface, and the plurality of connection vias of the second via layer 133 may have a tapered shape of which a width of the lower surface is wider than a width of the upper surface. The first and second via layers 132 and 133 may include the same seed layer and plating layer included in the first and second wiring layers 121 and 122. When the first and second insulating layers 112 and 113 are a plurality of layers, each of the first and second via layers 132 and 133 may be a plurality of layers.

Each of the first and second passivation layers 141 and 142 may include an organic insulating material. The organic insulating material may include a thermosetting resin such as epoxy resin, a thermoplastic resin such as polyimide, or a material including inorganic filler, organic filler, and/or glass fiber (glass cloth, glass fabric) along with the resin. Each of the first and second passivation layers 141 and 142 may have one or more first and second openings h1 and h2. A pad pattern of each of the first and second wiring layers 121 and 122 exposed through the first and second openings h1 and h2 may be in the form of Solder Mask Defined (SMD) and/or Non Solder Mask Defined (NSMD).

The electrical connection metal 151 may connect the printed circuit board 100A to another substrate, electronic component, or the like. The electrical connection metal 151 may be formed of a conductive material, for example, solder, or the like, but this is merely an example and the material is not particularly limited thereto. The plurality of electrical connection metals 151 may be lands, balls, pins, or the like, respectively. Each of the electrical connection metals 151 may be formed as a multilayer or a single layer structure. When the electrical connection metal 151 is formed as a multilayer structure, the electrical connection metal 151 may include a copper pillar and solder formed on the copper pillar, and when the electrical connection metal 151 is formed as a single layer, the electrical connection metal 151 may include tin-silver solder or copper, but the present disclosure is not limited thereto. The plurality of electrical connection metal 151 may be provided in plural forms.

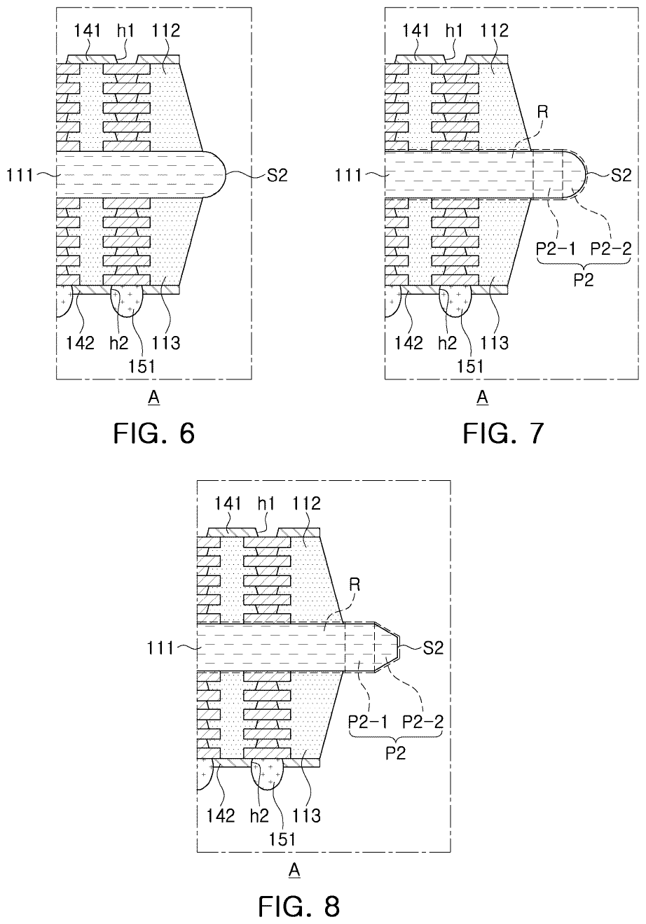

FIG. 6 is a cross-sectional view schematically illustrating a modified example of region A of FIG. 4.

Referring to FIG. 6, one or more first insulating layers 112 may have a tapered shape of which a width substantially narrows as a distance thereof from the upper surface of the glass substrate 111 increases in the first direction. In addition, one or more second insulating layers 113 may have a tapered shape of which a width substantially narrows as a distance thereof from the lower surface of the glass substrate 111 increases in the first direction. Thereby, stress applied to the glass substrate 111 may be effectively controlled. However, an embodiment thereof is not limited thereto, and the side surfaces of each of the one or more first and second insulating layers 112 and 113 may be formed as a substantially vertical surface, by adjusting a grinding depth, or the like. The other descriptions may be substantially the same as those described above.

FIG. 7 is a cross-sectional view schematically illustrating another modified example of region A of FIG. 4.

Referring to FIG. 7, the glass substate 111 may include an internal region R in contact with one or more first insulating layers 112 and/or one or more second insulating layers 113, and a second protruding region P2 spaced apart from the one or more first insulating layers 112 and/or the one or more second insulating layers 113. The second protruding region P2 may have a second end portion P2-2 having a second side surface S2 disposed thereon and a second connection portion P2-1 connecting the second end portion P2-2 to the internal region R. Similarly thereto, the glass substrate 111 may further include first, third, and fourth protruding regions respectively spaced apart from the one or more first insulating layers 112 and/or one or more second insulating layers 113. The first protruding region may have a first end portion having a first side surface S1 disposed thereon and a first connection portion connecting the first end portion to the internal region R. The third protruding region may have a third end portion S3 on which a third side surface is disposed and a third connection portion connecting the third end portion to the internal region R. The fourth protruding region may have a fourth end portion on which a fourth side surface S4 is disposed and a fourth connection portion connecting the fourth end portion to the internal region R. When viewed from the second direction, for example, in a cross-section thereof in the first-second directions, the second connection portion P2-1 may have a shape in which upper and lower surfaces thereof are substantially flat. For example, each of the second connection portions P2-1 may be a straight-line section of the second protruding region P2 and each of the first, third, and fourth protruding regions. Similarly thereto, when viewed from the second direction or the third direction, for example, in the cross-section in the first-second directions cross-section or the cross-section in the first-third directions, each of the first, third, and fourth connection portions may have a shape in which the upper and lower surfaces are substantially flat. For example, each of the first, third, and fourth connection portions may be a straight-line section of each of the first, third, and fourth protruding regions. When viewed from the second direction, for example, in the cross-section in the first-second directions, the second end portion P2-2 may have a substantially convex curved shape in the central portion. For example, the second end portion P2-2 may be a curved end section of the second protruding region P2. Similarly thereto, when viewed from the second or third direction, for example, in the cross-section in the first-second directions or the cross-section in the first-third directions, each of the first, third, and fourth end portions may have a substantially convex curved shape in the central portion. For example, each of the first, third, and fourth end portions may be a curved end section of each of the first, third, and fourth protruding regions. If necessary, the second end portion P2-2 and each of the first, third, and fourth end portions may have substantially vertical shapes. The effects according to the present disclosure may be more effectively achieved through the second protruding region P2 and the first, third, and fourth protruding regions. The other descriptions may be substantially the same as those described above.

FIG. 8 is a cross-sectional view schematically illustrating another modified example of region A of FIG. 4.

Referring to FIG. 8, the second end portion P2-2 of the second protruding area P2 described above may have a chamfer shape having a predetermined inclination, respectively. For example, when viewed from the second direction, for example, on a cross-section in the first-second directions, the second end portion P2-2 may have a substantially vertical surface in the central portion, and may have substantially inclined surfaces connected to the substantially vertical surface in the central portion in the upper and lower portions, respectively. Similarly thereto, each of the first, third and fourth end portions of each of the first, third and fourth protruding regions described above may have a chamfered shape having a predetermined inclination. For example, when viewed from the second or third direction, for example, in the cross-section in the first-second directions or the cross-section in the first-third directions, each of the first, third, and fourth end portions may have a surface which is substantially vertical in the central portion, and have a substantially inclined surface connected to the substantially vertical surface in the central portion in the upper and lower portions, respectively. These inclined surfaces may have an inclination angle of approximately 45 degrees or 60 degrees, but the present disclosure is not limited thereto. The connection portions of the substantially vertical surface and the substantially inclined surface may respectively be connected in a curved shape. As described above, the second protruding region P2 and each of the first, third, and fourth protruding regions may be manufactured in various shapes. The other descriptions may be substantially the same as those described above.

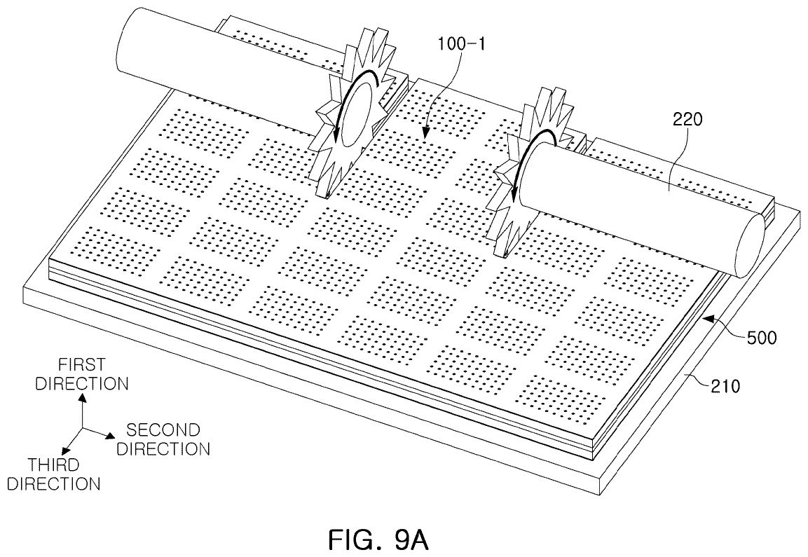

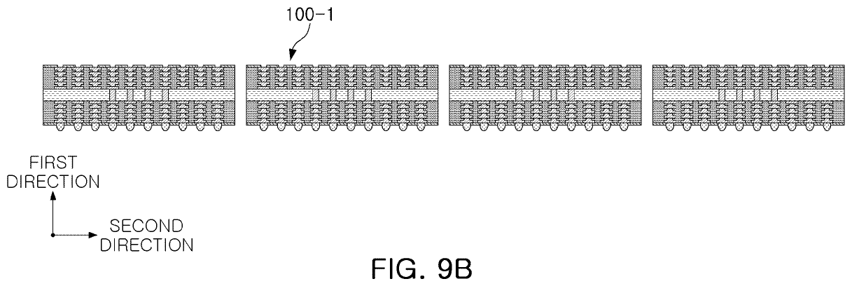

FIGS. 9A and 9B are schematic drawings illustrating cutting of a printed circuit board at a panel level using a singulation process using a blade.

Referring to FIGS. 9A and 9B, after a panel-level printed circuit board 500 are disposed on a table 210, a singulation process may be performed using a blade 220. As the result, a plurality of unit printed circuit boards 100-1 may be manufactured. All the side surfaces of each of the unit printed circuit board 100-1 may be substantially vertical. The other descriptions may be substantially the same as those described above.

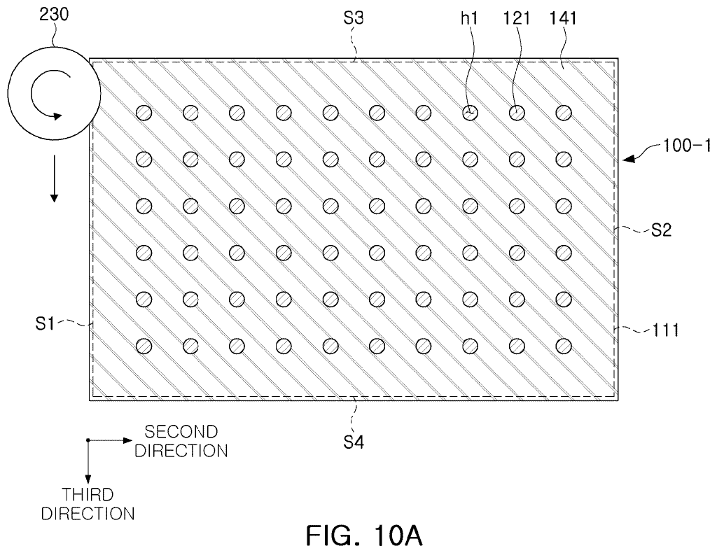

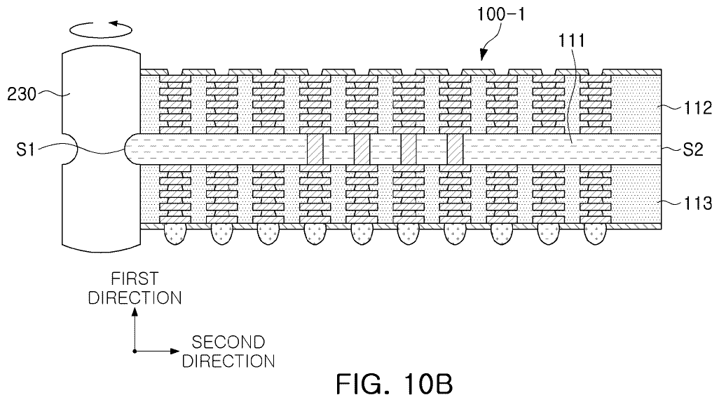

FIGS. 10A and 10B are schematic drawings illustrating a grinding process of each printed circuit board cut by a singulation process.

Referring to FIGS. 10A and 10B, grinding, or grinding and polishing, may be performed by applying a mortar-shaped grinding wheel 230 to each of unit printed circuit boards 100-1. In this case, four side surfaces of the first and second insulating layers 112 and 113 may be ground into flat or tapered inclined surfaces using the grinding wheel 230. In addition, a curved shape may be implemented on the four side surfaces S1, S2, S3, and S4 of the glass substrate 111 according to a curve value of the grinding wheel 230. The other descriptions may be substantially the same as those described above.

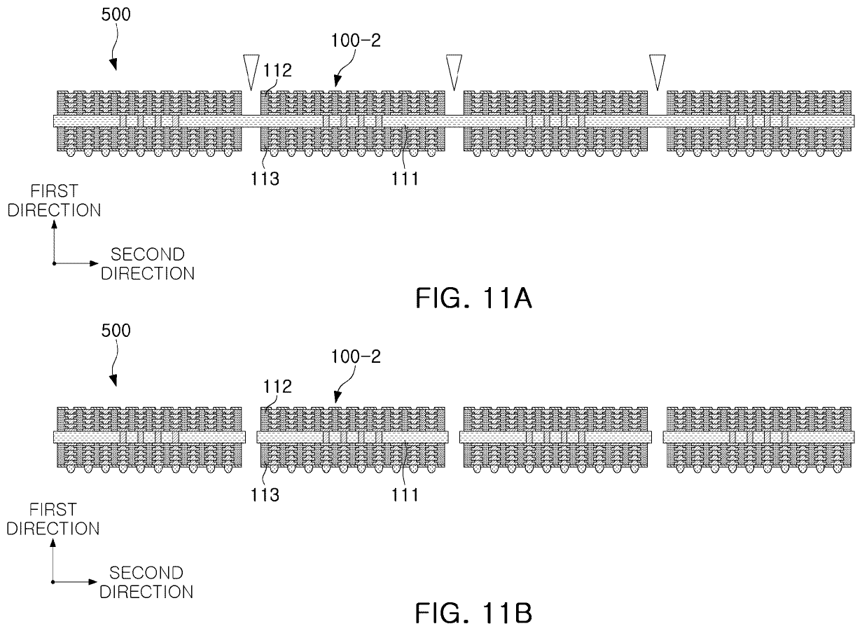

FIGS. 11A and 11B are schematic drawings illustrating cutting of a printed circuit board at a panel level using a singulation process using a laser.

Referring to FIGS. 11A and 11B, first, a panel-level printed circuit board 500 may be irradiated with a laser, to remove first and second insulating layers 112 and 113 between the unit printed circuit boards 100-2. As the result, a step may be formed between the glass substrate 111 and the first and second insulating layers 112 and 113. The step may be used as the above-described second protruding region P2 and the first, third, and fourth protruding regions of the glass substrate 111. Next, the glass substrate 111 may be cut through laser irradiation or laser irradiation and breaking, and as the result, a plurality of unit printed circuit boards 100-2 may be manufactured. Next, if necessary, grinding or grinding and polishing may be further performed using a grinding wheel in the shape of a mortar as described above. In this case, the first and second insulating layers 112 and 113 may be ground with a grinding wheel, but may not be ground. In addition, a curved shape may be implemented on the four side surfaces S1, S2, S3, and S4 of the glass substrate 111 according to the curve value of the grinding wheel. The other descriptions may be substantially the same as those described above.

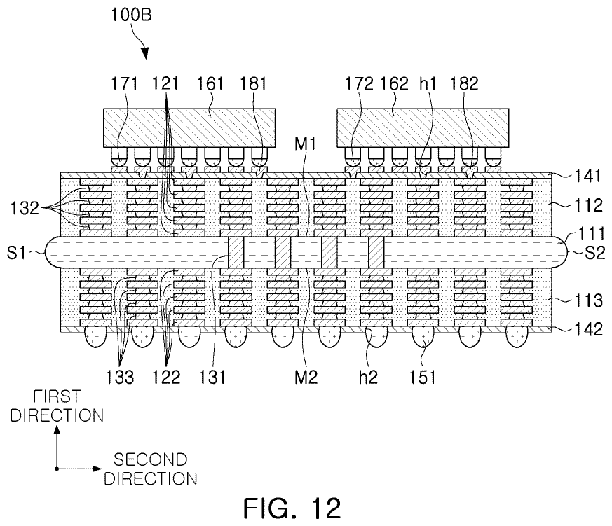

FIG. 12 is a cross-sectional view schematically illustrating a printed circuit board according to another example.

Referring to FIG. 12, in the printed circuit board 100A according to the above-described example, a printed circuit board 100B according to another example may further include one or more first electrode components 161 and 162 respectively disposed on a first passivation layer 141. Each of the one or more first electrode components 161 and 162 may be surface-mounted on the first passivation layer 141 through one or more conductive bumps 171 and 172. If necessary, one or more under bumps 181 and 182 may be further used for surface mounting. One or more first electrode components 161 and 162 may be the same as or different from each other. Each of the one or more first electrode components 161 and 162 may be a known active component and/or passive component. As a non-limiting example, the one or more first electronic components 161 and 162 may include a GPU and an HBM. Each of the one or more conductive bumps 171 and 172 may be a solder ball, but the present disclosure is not limited thereto. Each of the one or more under bumps 181 and 182 may include a metal material via and a metal material pad, but the present disclosure is not limited thereto. The printed circuit board 100B according to another example may be a semiconductor package structure including the printed circuit board 100A according to an example, and thus, the contents described in the printed circuit board 100A according to the example may be substantially identically applied. The other descriptions may be substantially the same as those described above.

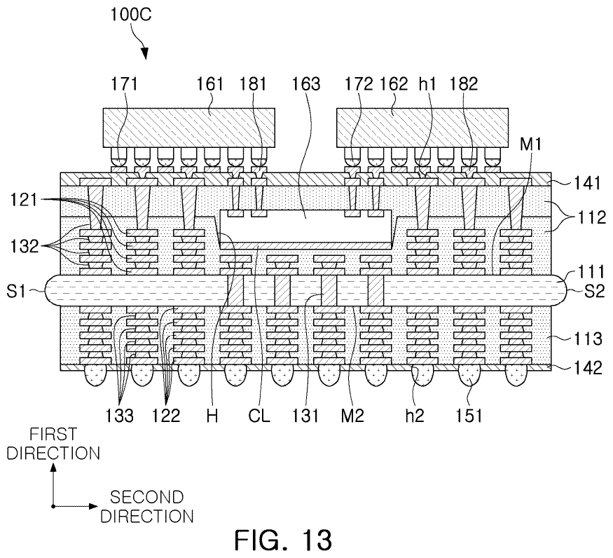

FIG. 13 is a cross-sectional view schematically illustrating a printed circuit board according to another example.

Referring to FIG. 13, a printed circuit board 100C according to another example may have a cavity H formed in one or more first insulating layers 112, in the printed circuit board 100B according to another example described above, and a second electronic component 163 may be further disposed in the cavity H. The second electronic component 163 may be embedded in one or more layers of the first insulating layer 112. The second electronic component 163 may be attached to a stopper layer CL in a face-up manner through a Die Attach Film (DAF) or the like. The second electronic component 163 may be a known interconnect bridge, but the present disclosure is not limited thereto. One or more first electronic components 161 and 162 may be connected to the second electronic component 163 through one or more first wiring layers 121 and one or more first via layers 132. A printed circuit board 100C according to another example may be a 2.1D package structure including a printed circuit board 100A according to an example, and thus the contents described for the printed circuit board 100A according to an example may be substantially equally applied. The other descriptions may be substantially the same as those described above.

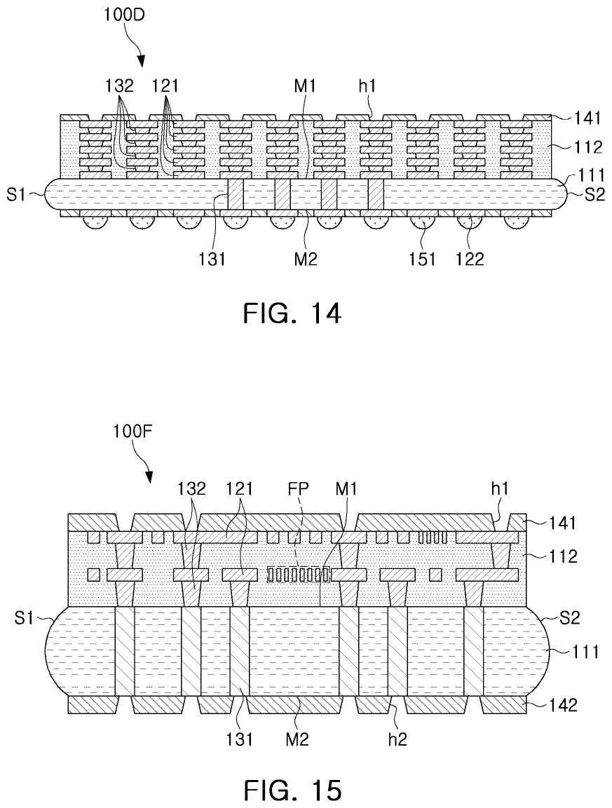

FIG. 14 is a cross-sectional view schematically illustrating a printed circuit board according to another example.

Referring to FIG. 14, in a printed circuit board 100D according to another example, one or more second insulating layers 113 and one or more second via layers 133 may be omitted, in the printed circuit board 100A according to the above-described example. For example, a printed circuit board 100D according to another example may have an asymmetric multilayer substrate structure in which a build-up layer is formed only on an upper side of a glass substrate 111. A printed circuit board 100D according to another example may include the configuration of a printed circuit board 100A according to an example, so that the contents described in the printed circuit board 100A according to an example may be substantially identically applied. Meanwhile, a printed circuit board 100D according to another example may be applied instead of a printed circuit board 100A according to an example to a printed circuit board 100B according to another example described above and a printed circuit board 100C according to another example. The other descriptions may be substantially the same as those described above.

FIG. 15 is a cross-sectional view schematically illustrating a printed circuit board according to another example.

Referring to FIG. 15, in a printed circuit board 100F according to another example, one or more second insulating layers 113, one or more second wiring layers 122, and one or more second via layers 133 may be omitted in the printed circuit board 100A according to the above-described example. In addition, a connection via of a first via layer 132 disposed on a lowermost side among one or more first via layers 132 may be directly connected to a through via of a through via layer 131. In addition, a microcircuit pattern FP having a relatively smaller line width and pitch compared to other wirings may be formed on the one or more first wiring layers. For example, a printed circuit board 100F according to another example may have a glass interposer structure. Since the printed circuit board 100F according to another example may include the component of the printed circuit board 100A according to an example, the contents described in the printed circuit board 100A according to an example may be substantially identically applied. Meanwhile, a printed circuit board 100F according to another example may be applied to a 2.5D package structure. The other descriptions may be substantially the same as those described above.

In the example embodiments, the term “covering” may include a case of covering at least partially as well as a case of covering completely, and may also include a case of covering not only directly but also indirectly. In addition, the term “filling” may include a case of completely filling but also a case of at least partially filling, and may also include a case of approximately filling. For example, the term “filling” may include a case in which, for example, some pores or voids exist. Also, the term “surrounding” may include not only a case of completely surrounding but also a case of partially surrounding, and a case of approximately surrounding. Also, the term “exposing” may include exposing partially as well as exposing completely, and “exposing” may refer to exposing from embedding a corresponding component. For example, exposing a pad by an opening may be exposing the pad from a resist layer, and a surface treatment layer or the like may be further disposed on the exposed pad.

In the example embodiments, being disposed within a through-portion or a through-hole may include not only a case in which an object is disposed completely within the through-portion or through-hole, but also a case in which the object partially protrudes upwardly or downwardly on a cross-section. For example, being disposed within a through-portion or a through-hole in the plane, this may be determined in a broader sense.

In the example embodiments, determination may be performed by including process errors, positional deviations, errors at the time of measurement, which may occur substantially in a manufacturing process. For example, being substantially vertical may include not only being completely vertical but also being approximately vertical. Also, being substantially a curve may include not only a case in which it is a completely curve, but also an approximately curve. For example, it can be judged by the overall shape.

In the example embodiments, the same insulating material may refer to not only the same insulating material but also the same type of insulating material. Accordingly, the composition of the insulating material may be substantially the same, but the specific composition ratio thereof may be slightly different.

In the example embodiment, the meaning on a cross-section may mean a cross-sectional shape when an object is vertically cut, or a cross-sectional shape when the object is viewed from the side. Also, the meaning on a plane may refer to a planar shape when the object is horizontally cut, or a planar shape when the object is viewed from the top or the bottom.

In the example embodiments, the terms “a lower side, a lower portion, a lower surface, the other surface”, and the like, are used to refer to a downward direction based on the cross-section of the drawing for convenience, and the terms “an upper side, an upper portion, an upper surface, one surface”, and the like, are used as the opposite directions. However, the direction is defined as above for ease of description, and the scope of the claims is not limited to any particular example by the descriptions of the directions.

In the example embodiments, the term “connected” may not only refer to “directly connected” but also include “indirectly connected” by may refer to of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, a thickness, a width, a length, a depth, a line width, a gap, a pitch, a separation distance, surface roughness, and the like, may be measured using a scanning microscope, an optical microscope, or the like, based on a cross-section a printed circuit board that has been polished or cut, respectively. The cut cross-section may be a vertical cross-section or a horizontal cross-section, and each value may be measured based on a required cut cross-section. For example, the width of the upper and/or lower portions of a via may be measured on a cross-section cut along the central axis of the via. In this case, when the value is not constant, the value may be determined as an average value of values measured at five arbitrary points.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as being relevant to the other example embodiment unless otherwise indicated.

The terms used herein describe particular embodiments only, and the present disclosure is not limited thereby. As used herein, the singular forms “a,” “an,” and “the” are intended to include the plural forms as well, unless the context clearly indicates otherwise.

As set forth above, as one of the effects of the present disclosure, a printed circuit board including a glass substrate, which can reduce cracks, or the like in the glass substrate due to singulation, and can also improve the strength of an edge of the glass substrate even after singulation, may be provided.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a glass substrate having an upper surface and a lower surface opposing each other in a first direction, a first side surface and a second side surface opposing each other in a second direction perpendicular to the first direction, and a third side surface and a fourth side surface opposing each other in a third direction perpendicular to the first and second directions, respectively; and
one or more first insulating layers disposed on the upper or the lower surface of the glass substrate,
wherein each of the first to fourth side surfaces of the glass substrate protrudes from at least a portion of side surfaces of the one or more first insulating layers in the second or third direction.

2. The printed circuit board of claim 1, wherein the glass substrate further has a first corner portion connecting the first and third side surfaces, a second corner portion connecting the first and fourth side surfaces, a third corner portion connecting the second and third side surfaces, and a fourth corner portion connecting the second and fourth side surfaces,
when viewed in the first direction, each of the first to fourth corner portions has a substantially curved shape.

3. The printed circuit board of claim 1, wherein when viewed from the second or the third direction, each of the first to fourth side surfaces has a substantially convex curved shape in a central portion.

4. The printed circuit board of claim 1, wherein the glass substrate includes an internal region in contact with the one or more first insulating layers and first to fourth protruding regions respectively protruding from the one or more first insulating layers,
the first protruding region has a first end portion on which the first side surface is disposed and a first connection portion connecting the first end portion to the internal region,
the second protruding region has a second end portion on which the second side surface is disposed and a second connection portion connecting the second end portion to the internal region,
the third protruding region has a third end portion on which the third side surface is disposed and a third connection portion connecting the third end portion to the internal region, and
the fourth protruding region has a fourth end portion on which the fourth side surface is disposed and a fourth connection portion connecting the fourth end portion to the internal region.

5. The printed circuit board of claim 4, wherein when viewed from the second or third direction, each of the first to fourth connection portions has a shape in which upper and lower surfaces of each of the first to fourth connection portions are substantially flat.

6. The printed circuit board of claim 5, wherein when viewed from the second or third direction, each of the first to fourth end portions has a substantially convex curved shape in a central portion.

7. The printed circuit board of claim 5, wherein when viewed from the second or third direction, each of the first to fourth end portions has a substantially vertical surface in a central portion and has a substantially inclined surface connected to the substantially vertical surface.

8. The printed circuit board of claim 1, further comprising:
one or more second insulating layers disposed on the lower surface or upper surface of the glass substrate,
wherein the glass substrate is disposed between the one or more first insulating layers and the one or more second insulating layers in the first direction, and
each of the first to fourth side surfaces of the glass substrate protrudes from at least a portion of the side surfaces of the one or more second insulating layers in the second or third direction.

9. The printed circuit board of claim 8, wherein the one or more first insulating layers have a tapered shape of which a width substantially narrows as a distance from the upper surface or lower surface of the glass substrate increases in the first direction, and
the one or more second insulating layers have a tapered shape of which a width substantially narrows as a distance from the lower surface or upper surface of the glass substrate increases in the first direction.

10. The printed circuit board of claim 8, further comprising:
a through-via layer penetrating at least a portion of the glass substrate;
one or more first wiring layers respectively disposed on or within the one or more first insulating layers;
one or more first via layers respectively penetrating at least a portion of at least one of the one or more first insulating layers;
one or more second wiring layers respectively disposed on or within the one or more second insulating layers; and
one or more second via layers respectively penetrating at least a portion of at least one of the one or more second insulating layers.

11. The printed circuit board of claim 10, further comprising:
a first passivation layer disposed on a first insulating layer disposed on an uppermost side among the one or more first insulating layers, and having one or more first openings respectively exposing at least a portion of a first wiring layer disposed on an uppermost side among the one or more first wiring layers;
a second passivation layer disposed on a second insulating layer disposed on a lowermost side among the one or more second insulating layers, and having one or more second openings respectively exposing at least a portion of a second wiring layer disposed on a lowermost side among the one or more second wiring layers; and
one or more electrical connection metals respectively disposed on the one or more second openings, and respectively connected to at least a portion of the exposed second wiring layer disposed on the lowermost side of the one or more second wiring layers.

12. The printed circuit board of claim 11, further comprising:
one or more first electronic components respectively disposed on the first passivation layer, and respectively connected to at least a portion of the first wiring layer disposed on the uppermost side among the one or more first wiring layers through one or more conductive bumps.

13. The printed circuit board of claim 12, further comprising:
a second electronic component disposed on a cavity penetrating at least a portion of the one or more first insulating layers and embedded in at least another portion of the one or more first insulating layers, and respectively connected to the one or more first electronic components through at least a portion of the one or more first wiring layers and the one or more first via layers.

14. A printed circuit board, comprising:
a glass substrate; and
an insulating layer disposed on the glass substrate,
wherein a side surface of the glass substrate protrudes outwardly from a side surface of the insulating layer, and on a cross-section, the protruding side surface of the glass substrate has a substantially convex curved shape in a central portion.

15. The printed circuit board of claim 14, wherein on a plane, an area of the glass substrate is greater than an area of the insulating layer.

16. The printed circuit board of claim 14, wherein the glass substrate includes plate glass, and
the insulating layer includes an organic insulating material.

17. A printed circuit board, comprising:
a glass substrate;
one or more first insulating layers disposed on an upper surface of the glass substrate;
one or more first wiring layers respectively disposed on or within the one or more first insulating layers; and
one or more first via layers respectively penetrating at least a portion of at least one of the one or more first insulating layers,
wherein the glass substrate includes a portion protruding outwardly from a flat side surface of the one or more first insulating layers.

18. The printed circuit board of claim 17, wherein the one or more first insulating layers have a tapered shape of which a width substantially narrows as a distance from the upper surface of the glass substrate increases.

19. The printed circuit board of claim 17, further comprising:
one or more second insulating layers disposed on a lower surface of the glass substrate;
one or more second wiring layers respectively disposed on or within the one or more second insulating layers; and
one or more second via layers respectively penetrating at least a portion of at least one of the one or more second insulating layers,
wherein the glass substrate includes the portion protruding outwardly from a flat side surface of the one or more second insulating layers.

20. The printed circuit board of claim 17, further comprising:
a through-via layer penetrating at least a portion of the glass substrate.
